(19) United States
(12) Patent Application Publication
(10) Pub. No.: US 2010/0044089 A1
(43) Pub. Date: Feb. 25, 2010

(54) INTERPOSER INTEGRATED WITH CAPACITORS AND METHOD FOR MANUFACTURING THE SAME

(76) Inventors: Akinobu Shibuya, Tokyo (JP); Yasuhiro Ishii, Tokyo (JP); Toru Mori, Tokyo (JP); Koichi Takemura, Tokyo (JP)

Correspondence Address: Mr. Jackson Chen, 6535 N. STATE HWY 161, IRVING, TX, 75039, US

(21) Appl. No.: 12/529,378

(22) PCT Filed: Feb. 28, 2008
(86) PCT No.: PCT/JP2008/053523

§ 371 Date: Sep. 1, 2009

(30) Foreign Application Priority Data
Mar. 1, 2007 (JP) 2007 051131

(51) Int. Cl. H05K 1/16; H05K 3/30

(52) U.S. Cl. 174/260; 29/832

(57) ABSTRACT

An interposer integrated with capacitors (100) includes a plug substrate (10) in which via-plugs (12) is formed, and a capacitor substrate (20) in which capacitors are formed. The capacitor substrate (20) includes a substrate body (21), capacitors (22) formed on the main surface of the substrate body, a cover insulating film (25) that covers the capacitors, a terminal electrodes (26) connected to the electrodes of the capacitor and formed on the cover insulating film, electrode pads (24) formed on the rear surface of the substrate body, and via-plugs 23 connecting together the terminal electrodes and electrode pads. The plug substrate (10) includes a substrate body (11), and electrode pads (13) formed on the main surface of the substrate body corresponding to the terminal electrodes of the capacitor substrate, and via-plugs (12) penetrating the substrate body and connected to the electrode pads.

This application is the National Phase of PCT/JP2008/053523, filed Feb. 28, 2008, which is based upon and claims the benefit of priority from Japanese patent application No. 2007-051131 filed on Mar. 1, 2007, the disclosure of which is incorporated herein in its entirety by reference.

### TECHNICAL FIELD

The present invention relates to an interposer integrated with capacitors and a method for manufacturing the same and, more particularly, to an interposer integrated with capacitors that is stacked between a semiconductor device (LSI) and a wiring board and a method for manufacturing the same.

### BACKGROUND ART

It is known in an LSI (large scale integration) that noise (switching noise) occurs upon a switching, such as a clock operation. A voltage drop ΔV occurring upon switching is generally expressed by the following formula (I):

ΔV=R×i−L×di/dt (1)

Here, R is an electrical resistance of an interconnection between the LSI and a power supply unit, “i” is a load current passing through the circuit due to the switching, and L is an inductance of the interconnection between the LSI and the power supply unit.

As a countermeasure against the switching noise in the LSI, a decoupling capacitor is provided between the LSI and a wiring board mounting thereon the LSI, in order for reducing the ΔV in the formula (I). The capacitor is arranged within the interposer substrate (capacitor-embedded interposer) that is mounted between the LSI and the wiring board, for example.

Recently, the clock frequency of the LSI reached the order of GHz, whereby it is impossible to neglect the inductance L1 caused by the interconnection provided between the LSI and the capacitor provided in the capacitor-embedded interposer. Therefore, it is requested to reduce the L1 as much as possible. For addressing this request, JP-2002-8942A proposes that the capacitor be formed on the substrate body 201 of the interposer 200, as shown in FIG. 16. In the same figure, the bottom electrode 203 and top electrode 205 of the capacitor are connected to a power source line 211 and a ground line 212, respectively.

In JP-2002-8942A, the capacitor is formed on the substrate body 201 including therein a via-plug 202, and an electrode pad 207 on the capacitor is connected to the LSI, thereby reducing the distance of interconnection between the LSI and the capacitor, and reducing the voltage drop caused by switching noise. However, since the substrate body 201 and via-plug 202 have different thermal coefficients of expansion in this capacitor-embedded interposer 200, the via-plug 202 expands and contracts due to the heat applied during forming the capacitor, thereby causing a risk of damage on the capacitor connected to the via-plug.

### SUMMARY OF THE INVENTION

In view of the above, it is an object of the present invention to provide an interposer integrated with capacitors wherein the damage of the capacitor caused by contraction of a via-plug can be suppressed, and to provide a method for manufacturing the same.

In order to achieve the above object, the present invention provides, in a first aspect thereof, an interposer integrated with capacitors including a plug substrate in which via-plugs are formed, and a capacitor substrate in which capacitors are formed, wherein: the capacitor substrate includes a first substrate body, the capacitors formed on a main surface of the first substrate body, a cover insulation film that covers the capacitors, terminal electrodes connected to electrodes of the capacitors and formed on the cover insulation film, an electrode pads formed on a rear surface of the first substrate body, and via-plugs that connect together the terminal electrodes and the coupling pads; the plug substrate includes a second substrate body, coupling pads formed on a main surface of the second substrate body corresponding to the terminal electrodes of the capacitor substrate, and via-plugs that penetrate the second substrate body and connected to the coupling pad; and the terminal electrode of the capacitor substrate and the coupling pads of the plug substrate are bonded together.

The present invention provides, in a second aspect thereof, an interposer integrated with capacitors including a plug substrate in which via-plugs are formed, and a capacitor substrate in which capacitors are formed, wherein: the capacitor substrate includes a first substrate body, the capacitors formed on a main surface of the first substrate body, a cover insulation film that covers the capacitors, terminal electrodes connected to electrodes of the capacitors and formed on the cover insulation film, and through-holes that expose the terminal electrodes through a rear surface of the first substrate body; the plug substrate includes a second substrate body, coupling pads formed on a main surface of the second substrate body corresponding to the terminal electrodes of the capacitor substrate, and via-plugs that penetrate the second substrate body and connected to the coupling pads; and the terminal electrodes of the capacitor substrate and the coupling pads of the plug substrate are bonded together.

The present invention provides, in a third aspect thereof, a method for manufacturing an interposer integrated with capacitors, including the steps of: forming capacitors on a main surface of a first substrate; covering the capacitors by an insulating film; forming a terminal electrodes of the capacitors that penetrate the insulating film; forming a second substrate including coupling pads connected to first via-plugs; bonding together the terminal electrodes of the first substrate and the coupling pads of the second substrate; grinding the first substrate on a rear surface thereof; selectively etching the first substrate from the ground rear surface thereof to form through-holes that expose the terminal electrodes of the first substrate.

The present invention provides, in a fourth aspect thereof, a method for manufacturing an interposer integrated with capacitors, including the steps of: forming a plurality of capacitors on a main surface of a first substrate; covering the capacitors by an insulating film; forming terminal electrodes of the capacitors that penetrate the insulating film; cutting the first substrate, on which the capacitors and terminal electrodes are formed, into a plurality of substrate pieces each including at least one of the capacitors; forming second substrate including coupling pads connected to first via-plugs; bonding together the terminal electrodes formed on the substrate pieces and the coupling pads of the second substrate; grinding the substrate pieces on a rear surface thereof; selectively etching the substrate pieces from the ground rear surface thereof to form through-holes that expose the terminal electrodes.

The above and other objects, features and advantages of the present invention will be more apparent from the following description, referring to the accompanying drawings.

### BRIEF DESCRIPTION OF THE DRAWINGS

FIG. 1 is a sectional view of an interposer integrated with capacitors according to an embodiment of the present invention.

FIG. 2 is an enlarged sectional view showing in detail the interposer integrated with capacitors of FIG. 1.

FIG. 3 is a sectional view showing the state of mounting the interposer integrated with capacitors of FIG. 1.

FIG. 4 is a sectional view showing an interposer integrated with capacitors according to a first exemplary modification of the embodiment.

FIG. 5 is a sectional view showing an interposer integrated with capacitors according to a second exemplified modification of the embodiment.

FIG. 6 is a sectional view showing an interposer integrated with capacitors according to a third exemplary modification of the embodiment.

FIGS. 7A to 7F are sectional views consecutively showing steps of a fabrication process of the interposer integrated with capacitors of FIG. 1.

FIGS. 8A to 8C are sectional views consecutively showing steps subsequent to step of FIG. 7A.

FIG. 9 is a sectional view showing a step of a fabrication process of an interposer integrated with capacitors according to a first example of the embodiment.

FIG. 10 is a sectional view showing a step subsequent to step of FIG. 9.

FIG. 11 is a sectional view showing a step subsequent to step of FIG. 10.

FIG. 12 is a sectional view showing a step subsequent to step of FIG. 11.

FIG. 13 is a sectional view showing a step of a fabrication process of an interposer integrated with capacitors according to a second example of the embodiment.

FIG. 14 is a sectional view showing a step subsequent to step of FIG. 13.

FIG. 15 is a sectional view showing a step subsequent to step of FIG. 14.

FIG. 16 is a sectional view of a conventional capacitor-embedded interposer.

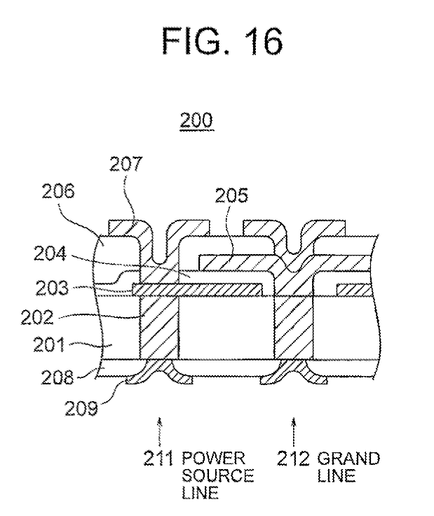

### DETAILED DESCRIPTION OF THE INVENTION

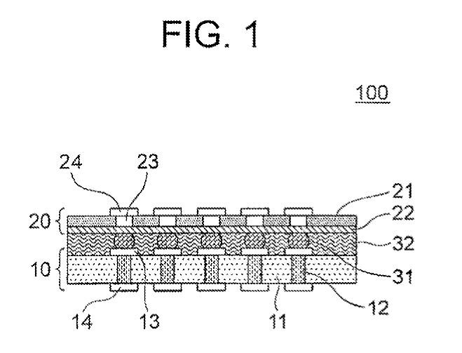

Hereinafter, an interposer integrated with capacitors according to an exemplified embodiment of the present invention and a method for manufacturing the same will be described in detail with reference to the accompanying drawings. In the accompanying drawings, similar reference numerals denote similar constituent elements. FIG. 1 is a sectional view showing the configuration of an interposer integrated with capacitors according to an embodiment of the present invention. The interposer integrated with capacitors 100 is inserted between a wiring board and an LSI, which are not illustrated, and includes a plug substrate 10 opposing the wiring board, and a capacitor substrate 20 mounted on the plug substrate 10 to oppose the LSI.

The plug substrate 10 includes a substrate body 11 and a plurality of via-plugs 12 penetrating the substrate body 11. On the main surface and rear surface of the substrate body 11, there are electrode pads 13 and 14 connected to the via-plugs 12. The electrode pads 13 may also be referred to as coupling pads in this text.

The capacitor substrate 20 includes a substrate body 21 and capacitors 22 formed on the substrate body 21. A plurality of via-plugs 23 penetrate the substrate body 21, and a plurality of electrode pads 24 connected to these plurality of via-plugs 23, respectively, are formed on the rear surface of the capacitor substrate 20. A plurality of terminal electrodes are formed on the main surface of the capacitor substrate 20.

The main surface of the plug substrate 10 and the main surface of the capacitor substrate 20 oppose each other, and the electrode pads 14 of the plug substrate and the terminal electrodes of the capacitor substrate 20 are coupled together via the bonding electrodes 31. A resin layer 32 fills the gap between the plug substrate 10 and the capacitor substrate 20.

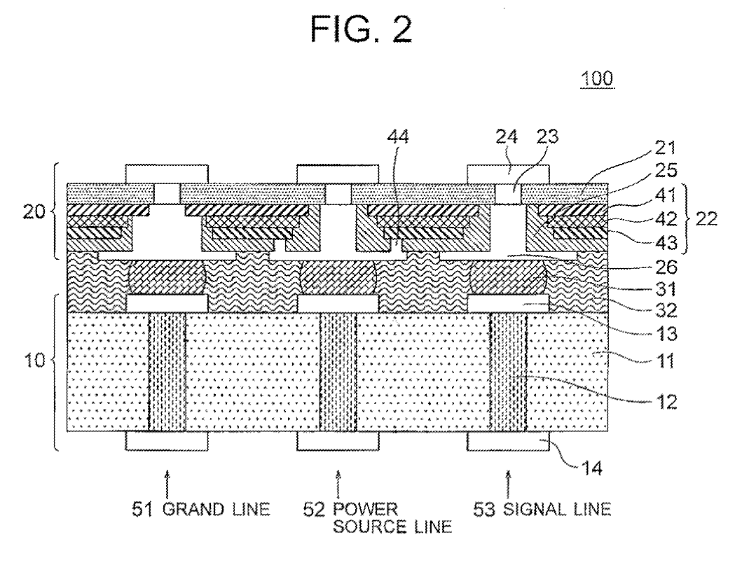

FIG. 2 is a sectional view showing in detail the configuration of a vicinity of the capacitor 22 while enlarging the capacitor-mounting interposer integrated with capacitors 100. The capacitor 22 is a MIM (metal-insulator-metal) capacitor, and includes a bottom electrode 41, a capacitor dielectric film 42, and a top electrode 43 which are consecutively formed on the main surface of the substrate body 21. Both materials of a bottom electrode 41 and a top electrode 43 are a metal or an alloy. A cover insulation film 25 is formed on the substrate body 21 to cover the capacitor 22. Terminal electrodes 26 are formed on the cover insulation film 25, to configure electrode pads for a connection use. The bottom of terminal electrodes 26 penetrate the cover insulation film 25, to be connected to the via-plugs 23.

The terminal electrode 26 that configures a ground line 51 has a bottom connected to the bottom electrodes 41. The terminal electrode 26 that configures a power source line 52 has an electrode pad portion connected to the top electrode 43 through a via-plug 44 formed in the cover insulation film 25. The terminal electrode 26 that configures a signal line 53 is not connected to any of the bottom electrode 41 and top electrode 43.

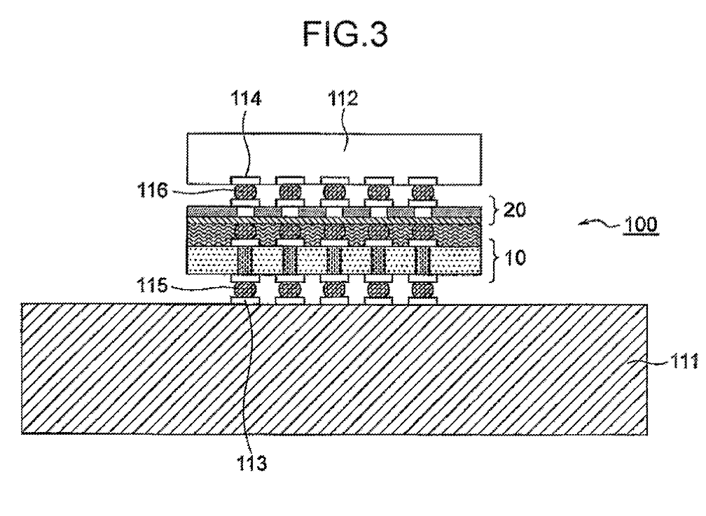

FIG. 3 is a sectional view showing the state of mounting the interposer integrated with capacitors 100. Upon mounting the interposer integrated with capacitors 100, the plug substrate 10 is coupled to the side of wiring board 111, whereas the capacitor substrate 20 is coupled to the side of LSI 112.

According to the present embodiment, the configuration wherein the plug substrate 10 and capacitor substrate 20 are coupled together via the bonding electrodes 31 allows separate fabrication of the plug substrate 10 and capacitor substrate 20. Thus, the step of forming the capacitors on the substrate including therein the via-plugs is obviated, thereby suppressing the damage of capacitors caused by contraction of the via-plugs. In addition, the separate fabrication of the plug substrate 10 and capacitor substrate 20 reduces the restriction on the fabrication.

Note in FIG. 1 that the technique for bonding together the electrode pads 13 and terminal electrodes 26 is not limited to the use of bonding electrodes 31 and, for example, the electrode pads 13 and terminal electrodes 26 may be directly bonded together. Although an example wherein the resin layer 32 fills the gap between the plug substrate 10 and the capacitor substrate 20 is shown, the gap need not be filled. However, filling by the resin layer 32 can suppress degradation of capacitors. The resin layer 32 may be replaced by a glass layer.

The material of substrate body 21 of the capacitor substrate is preferably, although not limited to, a material having a surface of a higher degree of smoothness, and may be a semiconductor substrate such as Si or GaAs, or an insulator substrate such as glass, ceramics, resin, or sapphire. Use of a non-insulating substrate, such as a semiconductor substrate, requires an insulating film formed on the surface thereof and sidewall of via-plug holes.

Although the thickness of substrate body 21 of the capacitor substrate is not limited, a smaller thickness thereof is preferred, in the view point of reduction in the distance of interconnection between the LSI and the capacitor for reducing the inductance L1, or facilitation of forming the via-plugs 23. For example, a thickness of 25 μm or less is preferred, and a thickness of 15 μm or less is more preferred.

Although the material of substrate body 11 of the plug substrate is not limited, a semiconductor substrate such as Si and GaAs, or an insulator substrate such as glass, sapphire, ceramics, glass-ceramic, or resin may be used therefor. Use of a non-insulating substrate, such as a semiconductor substrate, requires an insulating film formed on the surface thereof and the sidewall of via-plug holes.

Although the thickness of substrate body 11 of the plug substrate is not limited as well, a thickness that allows facilitation of handling and prevents destruction caused by a stress generated during the fabrication is preferred. Although the material of via-plugs 12 of the plug substrate is not limited, a metal, alloy, etc. are preferred therefor, and in particular, Cu, Ag or Au having a lower electrical resistance is more preferred.

Although the terminal electrode 26 connecting to the ground line 51 is connected to the bottom electrode 41, and the terminal electrode 26 connecting to the power source line 52 is connected to the top electrode 43 in FIG. 2, the connection may be reversed therefrom. The material of bottom electrodes 41 is preferably, although not limited to, such that the bottom electrodes have a higher adhesion capability with respect to the substrate body 21 and the material hardly diffuses into the material of the capacitor dielectric film 42. For example, it is preferred to include an active metallic film, such as Ti, Cr, Ta, or Mo, and a high-barrier-property metallic film, such as Pt, Ru, TiN, or Au, which are consecutively formed on the substrate body 21.

Although the material of the top electrode 43 is not limited as well, a material that hardly diffuses into the capacitor dielectric film 42 is preferred and, for example, Pt, Ru, TiN, or Au is preferred therefor. Although the technique of forming the bottom electrodes 41 and top electrodes 43 is not limited, a sputtering, CVD, evaporation, or plating technique is preferred therefor. Although the material of capacitor dielectric film 42 is not limited as well, a material that has a higher insulating property, such as tantalum oxide, aluminum oxide, or silicon oxide, is preferred therefor, and a compound that has a perovskite structure having a higher dielectric constant is more preferred.

As the compound having the perovskite structure, SrTiO₃ and (Sr,Ba)TiO₃ that are obtained by replacing a part of Sr in SrTiO₃ by Ba, or complex perovskite-type compounds that are obtained by replacing a part of Pb site or Ba site (A site) by Sr, Ca, La, etc., with PbTiO₃ or BaTiO₃ as the base structure to make the average valence of A site divalent and replacing a part Ti site (B site) by Mg, W, Nb, Zr, Ni, Zn, etc., to make the average valence of B site tetravalent are preferred.

Although the technique of forming the capacitor dielectric film 42 is not limited, a sputtering, CVD, or sol-gel process is preferred. Although the material of cover insulation film 25 is not limited, an inorganic insulator material such as SiO₂ and Si₃N₄, or resin such as polyimide and epoxy is preferred therefor. The thickness of cover insulation film 25 is not limited as well. Although the material of via-plugs 23 of the capacitor substrate is not limited, a metal or alloy is preferred therefor.

Although the material of terminal electrodes 26 of the capacitor is not limited, the material is preferably formed by plating, and Cu etc. are preferred. An adhesive layer such as Ti may be formed as an underlying layer for Cu. Although the thickness of Cu-plating layer is not limited, about 1 to 20 μm is preferred therefor. Upon connecting to the LSI, it is preferred to perform a surface treatment, such as using Au/Ni and Sn, on the rear surface. Although via-plugs 23 and electrode pads 24 are separately formed, these may be united. The material of electrode pad 24 is not limited.

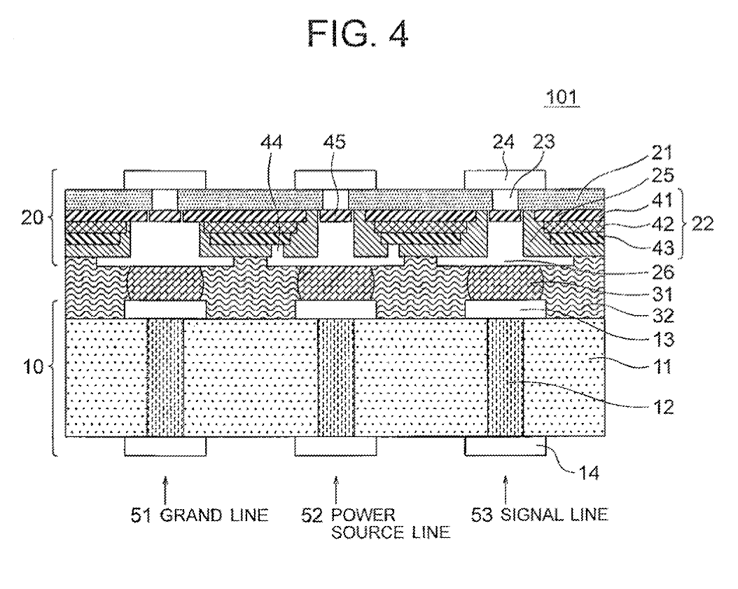

FIG. 4 is a sectional view of an interposer integrated with capacitors according to a first exemplified modification of the embodiment. A barrier metal film 45 is formed between the via-plug 23 and the terminal electrode 26 in the capacitor-mounting interposer integrated with capacitors 101. In this case, during forming the via-plugs 23 in the substrate body 21, the influence exerted onto the terminal electrode 26 is reduced.

Although the material of barrier metal film 45 is not limited, a metal, such as Ni, Cr, Mo, Pt, Ru, TiN, or TaN, or a compound including these metals is preferred therefor in the view point of effectively suppressing the influence on the terminal electrodes 26.

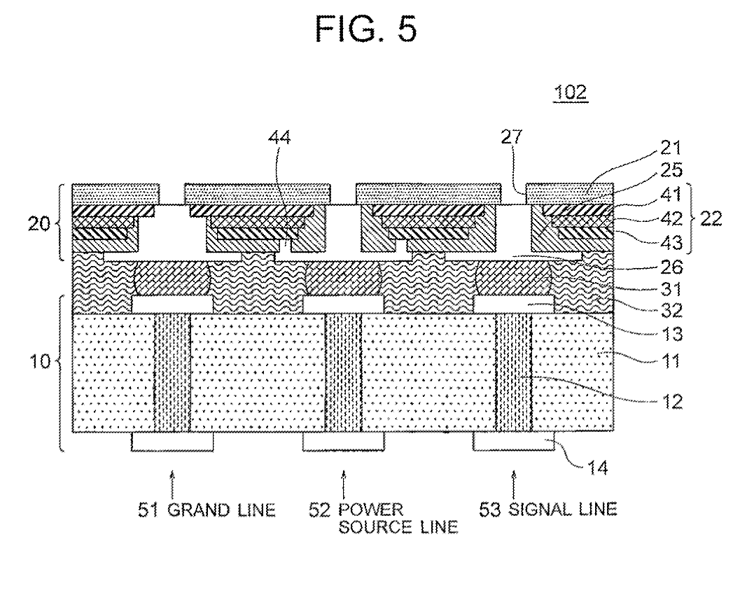

FIG. 5 is a sectional view of an interposer integrated with capacitors according to a second exemplified modification of the embodiment. In the interposer integrated with capacitors 102, via-plugs 23 and electrode pads 24 are not formed in the capacitor substrate 20, and the rear surface of the terminal electrodes 26 is exposed in the via-plug holes 27. If the thickness of the substrate body 21 is small enough in the capacitor substrate 20, connection to the LSI can be achieved by forming the bonding electrodes directly onto the rear surface of the terminal electrodes 26, without forming the via-plugs 23 and electrode pads 24.

In this modification, it is not needed to form the via-plugs 23 or electrode pads 24 in the capacitor substrate 20, thereby reducing the fabrication cost as compared to the interposer integrated with capacitors 100 shown in FIG. 2.

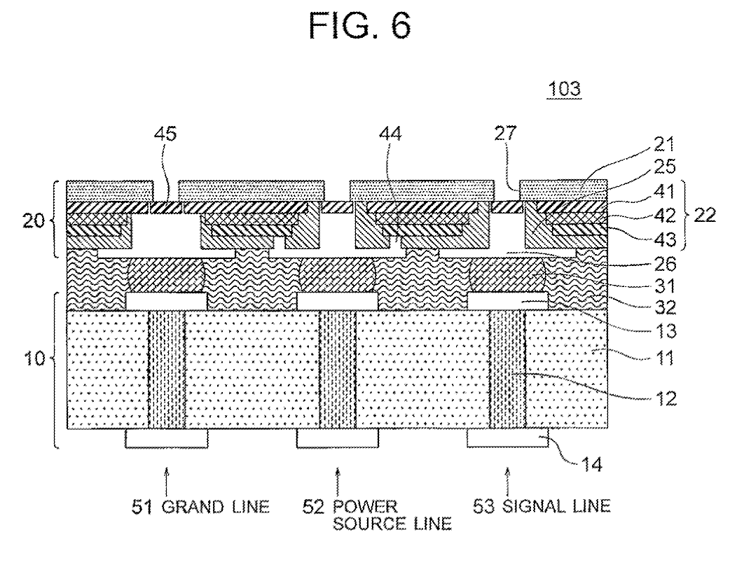

FIG. 6 is a sectional view of a capacitor-mounting an interposer integrated with capacitors according to a third exemplified modification of the embodiment. The interposer integrated with capacitors 103 is such that a barrier metal film 45 is formed on the rear surface of the terminal electrodes 26 in the interposer integrated with capacitors 102 of FIG. 5. As the barrier metal 45, an Au plating layer and a Ni plating layer are preferably formed on the top surface, if connection is performed to the LSI by using a solder. In addition, if Au—Au bonding is intended, an Au plating layer having a thickness of 1 μm or more is preferred.

In the interposer integrated with capacitors 102 shown in FIG. 5, or interposer integrated with capacitors 103 shown in FIG. 6, the thickness of substrate body 21 of the capacitor substrate is preferably 25 μm or less, and more preferably 15 μm or less.

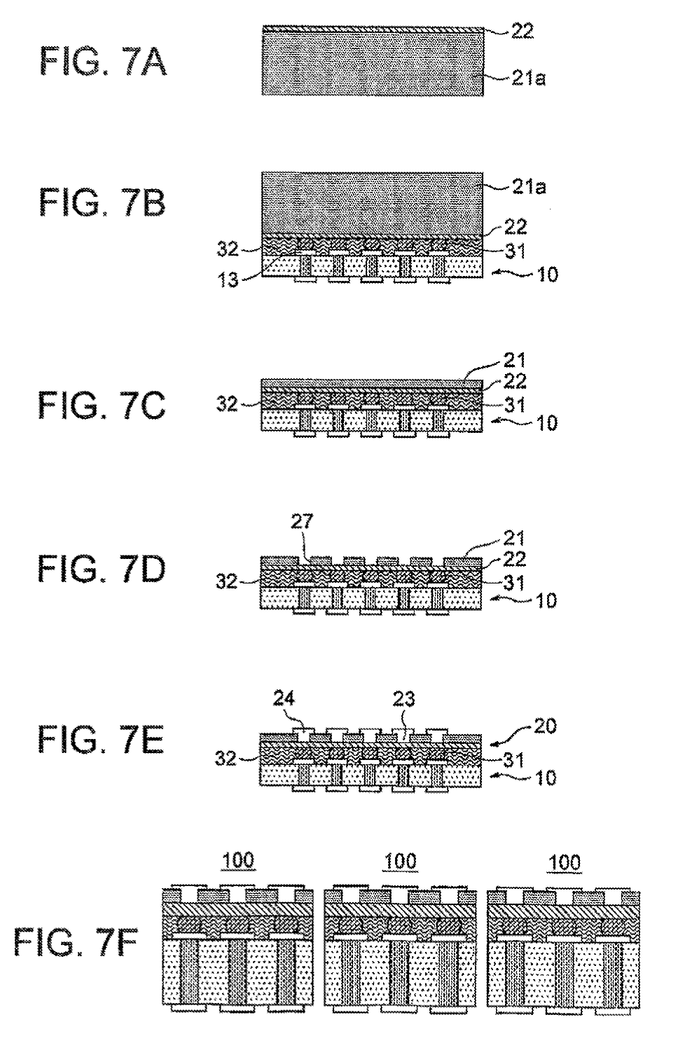

FIGS. 7A to 7F are sectional views consecutively showing fabrication steps during manufacturing the interposer integrated with capacitors 100 shown in FIG. 1. To begin with, as shown in FIG. 7A, a base substrate 21a having a thickness significantly larger as compared to the substrate body 21 is prepared, and capacitors 22 and terminal electrodes are formed on the main surface of the base substrate 21a. The terminal electrodes thus formed have a structure wherein via-plugs 23 can be later connected thereto from the bottom side thereof. Subsequently, the plug substrate 10 is formed using a known technique. Upon forming the plug substrate 10, via-plugs 12 are formed corresponding to the arrangement of the capacitors 22 and terminal electrodes formed on the base substrate 21.

Thereafter, electrode pads 13 of the plug substrate 10 and the terminal electrodes of the capacitor substrate 20 are bonded together via the bonding electrodes 31. The gap between the plug substrate 10 and the capacitor substrate 20 is filled with a resin layer 32 (FIG. 7B). Although the material of the bonding electrodes 31 is not limited, solder, Au etc. are preferred therefor. In an alternative, the electrodes of the plug substrate 10 and electrodes of the capacitor substrate 20 may be directly bonded together, without the intervening bonding electrode 31.

Thereafter, as shown in FIG. 7C, the base substrate 21a is subjected to grinding from the rear surface thereof to reduce the thickness thereof, thereby forming the substrate body 21. Although the thickness of the substrate body 21 is not limited, a thickness of about 10 to 15 μm is needed in order not to generate defects such as a crack, on the substrate body 21. Although the technique of grinding is not limited, a dry etching process, such as RIE (reactive ion etching), that follows an ordinary grinding process will reduce the grinding micro cracks on the substrate surface, and suppress occurrence of a stress caused by the grinding micro cracks.

Thereafter, as shown in FIG. 7D, via-plug holes 27 are formed in the substrate body 21. If the substrate body 21 is configured by a non-insulating substrate, such as a semiconductor substrate, an insulating film is formed on the rear surface of the substrate body 21 and the sidewall of the via-plug holes 27, after forming the via-plug holes 27. Although the material of this insulating film is not limited, resin is preferred therefor because it is needed to form the same at the temperature that does not affect the bonding electrodes 31.

After filling the via-plug holes 27 with a conductive material to form therein via-plugs 23, the electrode pads 24 connected to the via-plugs 23 are formed on the rear surface of the substrate body 21 (FIG. 7E). The via-plugs 23 and electrode pads 24 may be formed at the same time. Subsequently, the plug substrate 10 and capacitor substrate 20 which are unified together are subjected to cutting in accordance with LSIs, as shown in FIG. 7F, thereby manufacturing the interposer integrated with capacitors 100 shown in FIG. 1.

In the fabrication method of the present embodiment, the grinding process that reduces the thickness of base substrate 21a is performed after fixing the base substrate 21a onto the plug substrate 10. Accordingly, a substrate body 21 having a reduced thickness can be formed while suppressing the damage of the base substrate 21a. The capability of forming the substrate body 21 having a smaller thickness reduces the distance of interconnection between the LSI and the capacitors, to thereby reduce the inductance L1.

The capability of forming the substrate body 21 having a smaller thickness facilitates formation of the via-plug holes 27, whereby the range of choice for the material of the substrate body 21 can be increased. In addition, upon forming the via-plugs 23, filling of the via-plug holes 27 with a conductive material can be performed with ease.

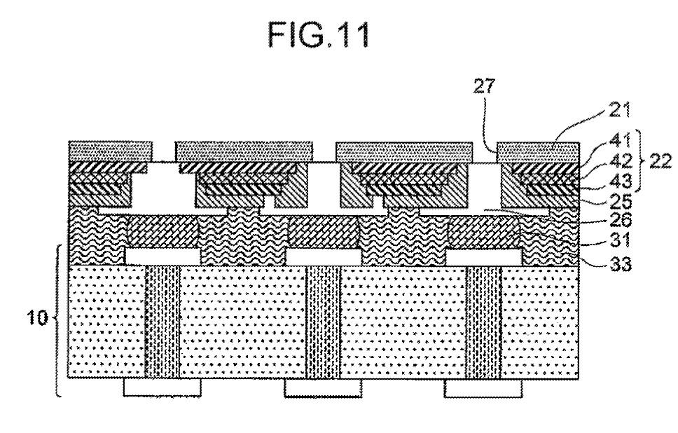

In order to obviate the step of forming capacitors on the substrate that includes via-plugs, it may be considered to employ a fabrication process that forms capacitors on the substrate body 201 in the interposer integrated with capacitors shown in FIG. 11 prior to forming the via-plugs 202, and thereafter forms the via-plugs 202 on the substrate body 201. However, in this fabrication process, there is a problem in that a crack occurring on the substrate body 201 during forming the via-plugs 202 may extend to the capacitors to damage the same, and in addition, formation of the via-plug holes on the substrate body 201 limits an etching condition that does not affect the bottom electrodes 203 already formed therein.

On the other hand, since the fabrication method of the present embodiment satisfactorily reduces the thickness of the substrate body 21 prior to forming the via-plugs 23, formation of the via-plug holes 27 is facilitated to thereby alleviate the etching condition, and suppress occurrence of the crack on the substrate body 21 during forming the via-plugs 23.

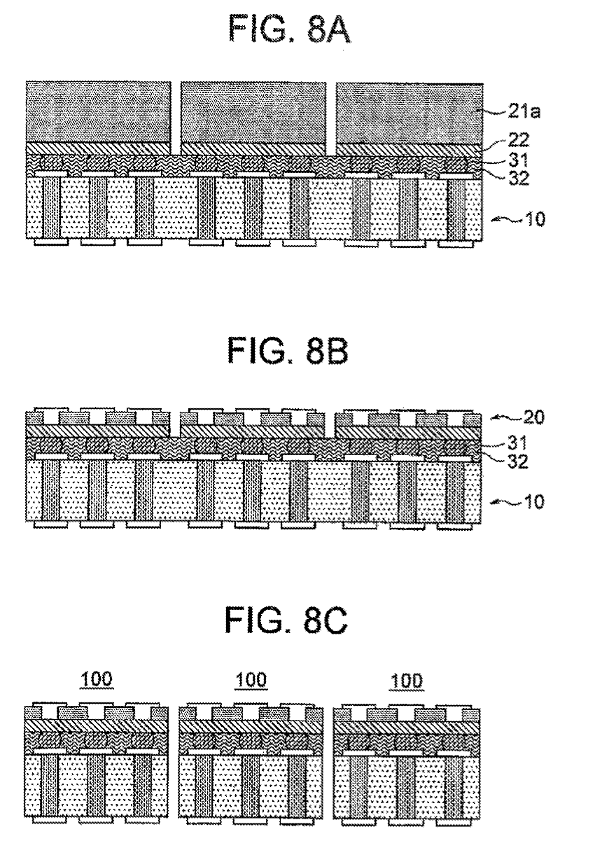

Although the above fabrication process is such that the plug substrate 10 and capacitor substrate 20 which are unified together are subjected to cutting, the base substrate 21a may be cut in advance prior to coupling together the plug substrate 10 and base substrate 21a. In this fabrication process, the base substrate 21a is subjected to cutting in accordance with the capacitor cells, subsequent to the step of FIG. 7A, for example. Thereafter, the base substrate 21a thus cut is connected to the plug substrate 10, as shown in FIG. 8A. Thereafter, performing a procedure similar to that shown in FIGS. 7C to 7E, the structure shown in FIG. 8B is obtained. As shown in FIG. 8C, the capacitor-mounting interposer integrated with capacitors 100 shown in FIG. 1 can be manufactured by cutting the plug substrate 10 in accordance with the LSIs.

In the fabrication process shown in FIGS. 8A to 8C, each base substrate 21a obtained by cutting the base substrate 21a is examined, and only the non-defective ones are used. Thus, an interposer integrated with capacitors 100 having a higher reliability can be efficiently manufactured, even if the product yield of the capacitor substrates 20 is lower.

### First Example

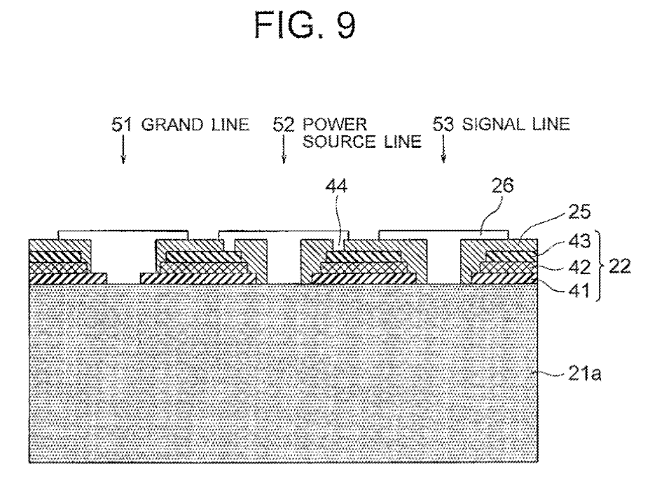

FIGS. 9 to 12 are sectional views consecutively showing respective fabrication steps of a method for manufacturing the interposer integrated with capacitors according to a first example of the present invention. In this example, an interposer integrated with capacitors similar to that shown in FIG. 2 was actually manufactured in accordance with the procedure of FIGS. 7A to 7F. To begin with, a 4-inch silicon wafer was prepared as the base substrate 21a, and was subjected to thermal oxidation of the main surface of the base substrate 21a in steam ambient at 900° C., to form thereon a 200-nm-thick oxide film.

Thereafter, a Ta film and a Ru film were consecutively formed as the bottom electrode 41 on the oxide film, by using DC magnetron sputtering. The thickness of Ta film and Ru film was 50 nm each. Subsequently, a SrTiO₃ (STO) film doped with 5 molecular % Mn as MnO₂ was formed to a thickness of 50 nm as the capacitor dielectric film 42, by using RF sputtering at a substrate temperature of 400° C. Thereafter, DC magnetron sputtering using nitrogen as a process gas was performed while using Ti as a target, to deposit a TiN film to a thickness of 100 nm, as the top electrode 43.

After forming a resist pattern on the TiN film, the TiN film was etched using the resist pattern as a mask and using a mixed water solution including ammonia, hydrogen peroxide solution and water, to form the top electrode 43. Subsequently, the resist pattern was removed by methyl-ethyl-ketone washing and oxygen plasma cleaning. After forming a resist pattern that covers the top electrode 43 on the STO film, the STO film was etched by using the resist pattern as the mask and using the mixed water solution including hydrofluoric acid and nitric acid, to thereby form the capacitor dielectric film. Thereafter, the resist pattern was removed by a similar washing process.

After forming a resist pattern that covers the top electrode 43 and capacitor dielectric film 42 on the Ru film, Ar ion milling was performed using the resist pattern as a mask, thereby patterning the Ta film and Ru film to form the bottom electrode 41. Subsequently, the resist pattern was removed by a similar washing process. Thus, a MIM capacitor 22 was formed.

Subsequently, photosensitive polyimide was applied using a spin coating. Thereafter, the photosensitive polyimide was subjected to patterning using exposure and development, to expose a part of the base substrate 21a, bottom electrode 41 and top electrode 43, as the portion to contact the terminal electrode 26 to be formed later. Thereafter, the polyimide was cured for two hours in a nitrogen gas at 320° C., to form the cover insulation film 25. The thickness of cover insulation film 25 after the curing was 1.5 μm.

Thereafter, a 50-nm-thick Ti film and a 300-nm-thick Cu film were consecutively deposited on the base substrate 21a, as the seed layers for electroplating, followed by the electroplating using the resist pattern as a mask to form a Cu layer on the Cu film, to thereby form terminal electrodes 26. After removing the resist pattern and the seed layers, electroless plating was performed to consecutively form Ni and Au to a thickness of 3 μm and 0.05 μm, respectively, on the terminal electrodes 26. Thus, the structure shown in FIG. 9 was obtained.

Of those terminal electrodes 26, terminal electrode to be connected to the ground line 51 was connected to the bottom electrode 41, terminal electrode to be connected to the power source line 52 was connected to the top electrode 43, and terminal electrode 26 to be connected a signal line 53 was not connected to any of the bottom electrode 41 and top electrode 43.

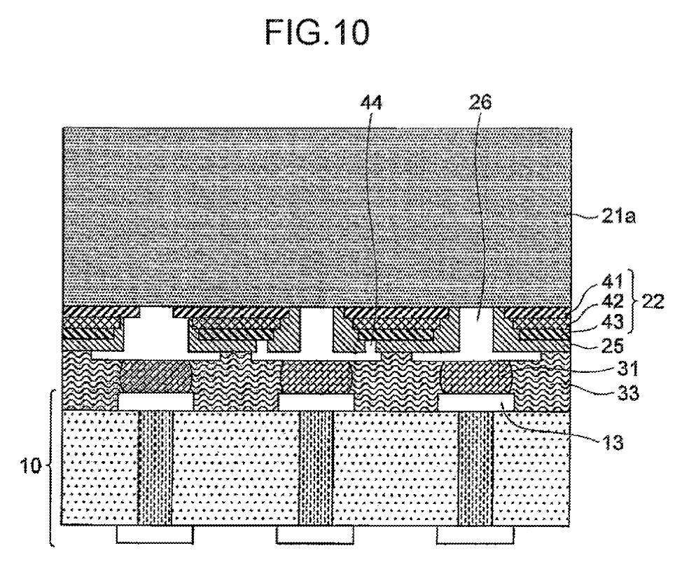

Thereafter, the plug substrate 10 was formed using a known technique. Using a photosensitive glass having a thickness of 300 μm as the substrate body 11 of the plug substrate, via-plugs 12 having a 50-μm-φ were formed therein. Cu was used for the via-plugs 12 and electrode pads 13 and 14, and the surface of the electrode pads 13 and 14 was applied with Ni and Au plating similarly to the terminal electrodes 26. Subsequently, the electrode pads 13 formed in the plug substrate 10 and the terminal electrodes 26 were bonded together via the bonding electrodes 31 including Sn—Ag—Cu solder. Subsequently, the gap between the plug substrate 10 and the cover insulation film 25 and terminal electrodes 26 is filled with an under-filling resin layer 33 (FIG. 10).

After grinding the rear surface of the base substrate 21a, RIE was performed onto the rear surface of the thus ground base substrate 21a, to from the substrate body 21 having a thickness of about 15 μm. After forming a resist pattern on the rear surface of the substrate body 21, RIE was performed using SF₆ as a reactant gas to form 40-μm-φ via-plug holes 27 in the substrate body 21 (FIG. 11).

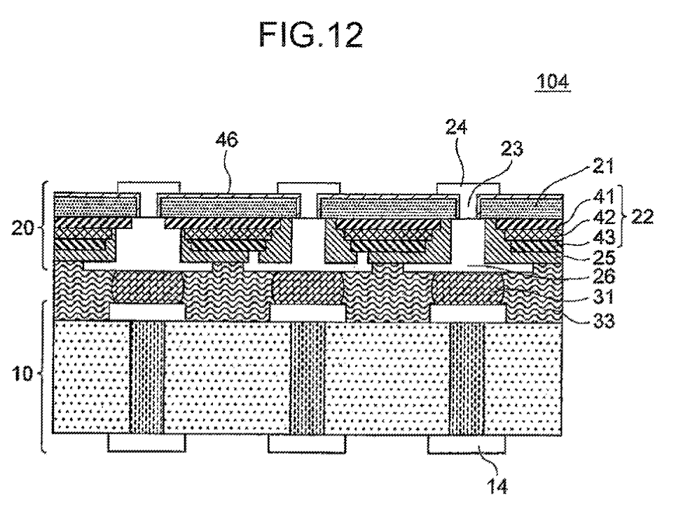

Subsequently, an insulating film 46 made of photosensitive epoxy phenol resin was formed by application onto the rear surface of the substrate body 21 and the rear surface and side surface of the via-plug holes 27, followed by exposure and development to remove the rear surface of the via-plug holes 27 and expose therefrom the rear surface of the terminal electrodes 26. Subsequently, as the seed layers for electroplating, a 50-nm-thick Ti film and a 300-nm-thick Cu film were consecutively formed on the base substrate 21a. After forming a resist pattern on the rear surface of the substrate body 21, electroplating was performed using the resist pattern as a mask to form a Cu layer on the Cu film, and thereby form the via-plugs 23 and electrode pads 24 in unison at the same time (FIG. 12).

Thereafter, the plug substrate 10 and capacitor substrate 20 which were coupled together were subjected to cutting to manufacture interposers integrated with capacitors 104. Upon the cutting, a size was of 20-mm square (□120 mm) receiving therein 8000 terminal electrodes 26 was selected.

In this example, since the substrate body 21 of the capacitor substrate was not handled alone in the state of a smaller thickness, the handling during the manufacture was facilitated. The smaller thickness of the substrate body 21 facilitated formation of the via-plug holes 27 even without using a special etching technique such as an ICP (inductively coupled plasma) etching technique etc. In addition, since the aspect ratio of the via-plug holes 27 was also small, the via-plugs 23 and electrode pads 24 could be formed at the same time by using an ordinary electroplating technique. The interposer integrated with capacitors 104 thus manufactured achieved a capacitance of 7.0 μF for each capacitor.

In the interposer integrated with capacitors 104 thus manufactured, a 3-μm-thick Ni film and a 0.05-μm-thick Au film were consecutively formed by electroless plating on the electrode pads 24 of the capacitor substrate and the electrode pads 14 of the plug substrate. Subsequently, the electrode pads 24 of the capacitor substrate was connected to the LSI, and electrode pads 14 of the plug substrate was connected to the electrode pads of the wiring board, both via the bonding electrodes made of Sn—Ag—Cu solder, to obtain the structure shown in FIG. 3.

Evaluation of decoupling characteristic was performed while operating the LSI on a power source voltage of 1V at a clock frequency of 2 GHz and a maximum load current of 100 A, to reveal achievement of an excellent characteristic.

### Second Example

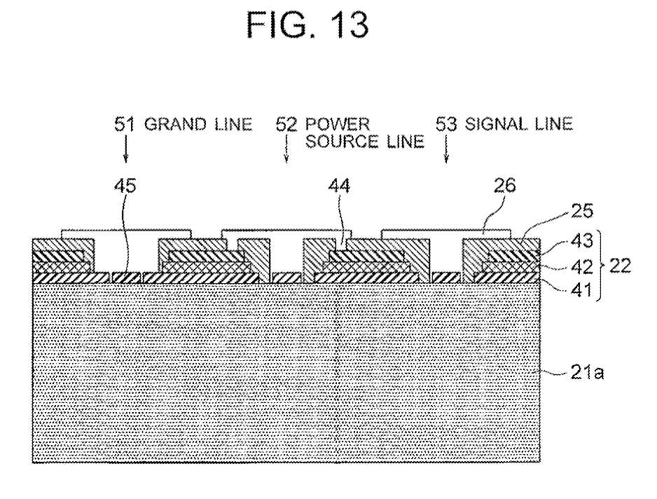

FIGS. 13 to 15 are sectional views consecutively showing fabrication steps of a process for manufacturing the interposer integrated with capacitors according to a second example of the present invention. In this example, an interposer integrated with capacitors similar to that shown in FIG. 6 was actually manufactured in accordance with the procedure of FIGS. 7A to 7E and FIGS. 8A to 8C. An alkali-free glass was used as the base substrate 21a of the capacitor substrate, and the capacitors 22, cover insulation film 25, terminal electrodes 26, and barrier metal film 45 were formed on the base substrate 21a, to obtain the structure shown FIG. 13.

As the materials of the bottom electrode 41, capacitor dielectric film 42, top electrode 43, and cover insulation film 25 of the capacitor, materials similar to those in the first example were used. The barrier metal film 45 was formed as the same layer as the bottom electrode 41, and configured by stacked Ta film and Ru film. Subsequently, the base substrate 21a on which a cover insulation film 25 had been formed was cut into unit capacitor cells.

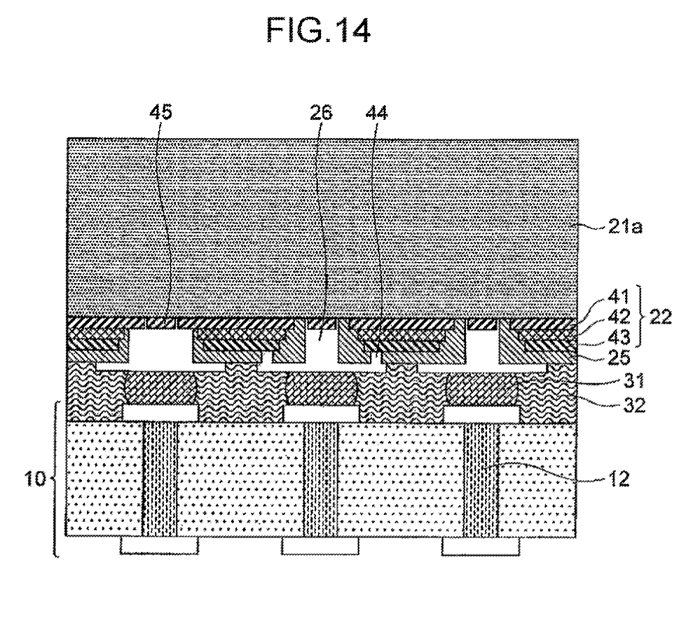

Thereafter, the plug substrate 10 was formed using a known technique. As the plug substrate 10, a co-fired glass-ceramic substrate was used that included the substrate body 11 configured by a glass-alumina ceramic composite, and via-plugs 12 configured by a Ag—Pd alloy. Subsequently, the base substrate 21a that was cut into unit capacitor cells was separately connected to the plug substrate 10 (FIG. 14). This process corresponds to the process shown in FIG. 8A.

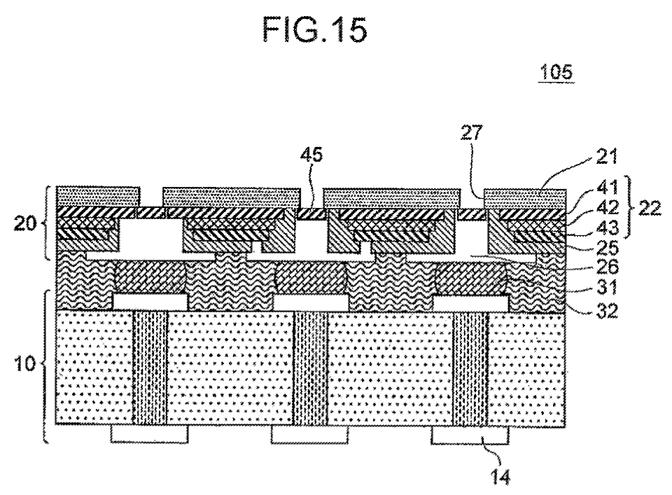

Subsequently, the rear surface of the base substrate 21a was subjected to grinding, to reduce the thickness thereof down to 15 μm, to form the substrate body 21. After forming a resist pattern on the rear surface of the substrate body 21, 50-μm-φ via-plugs were formed by an ICP etching process using a mixed gas including SF₆, CHF₃ and O₂ as a reactant gas. A 3-μm-thick Ni film and a 1-μm-thick Au film were consecutively formed on the surface of the barrier metal film 45 and electrode pads 14 of the plug substrate by using electroless plating, followed by cutting the plug substrate 10. Upon the cutting, a size of 20-mm square including therein 8000-terminal electrodes 26 was selected similarly to the first example. In this way, the capacitor-mounting interposer integrated with capacitors 105 shown in FIG. 15 was manufactured.

Due to the fact that the glass used for the substrate body 21 for the capacitor has a lower cost, and the glass has an insulating property that obviates formation of the insulating film on the surface thereof, the interposer integrated with capacitors 105 was manufactured at a lower cost as compared to the first example. The fact that none of the via-plugs 23 and electrode pads 24 was formed in the capacitor substrate 20 was also advantageous for the lower cost.

In general, it is not easy to form via-plug holes 27 having a higher aspect ratio by using dry etching, such as ICP etching and RIE, in a glass other than the silica glass. However, since the rear surface of the base substrate 21a was subjected to the grinding to reduce the thickness thereof in this example, the via-plug holes 27 thus formed has a reduced aspect ratio, whereby the via-plug holes 27 could be formed by etching with ease. The capacitors 105 mounted on the thus manufactured interposer achieved a capacitance of 6.9 μF.

The electrode pads 24 of the capacitor substrate were connected to the electrode pads of the LSI by using an Au—Au compression bonding, to thereby connecting the electrode pads of the wiring board to the electrode pads of the plug substrate via the bonding electrodes including Sn—Ag—Cu solder. Evaluation of the decoupling characteristic under the condition similar to that in the first example revealed that an excellent characteristic similar to the first example could be obtained.

According to the fabrication process of the interposer integrated with capacitors of the embodiment, the separate fabrication of the plug substrate and capacitor substrate obviates the step for forming the capacitors on the substrate having therein via-plugs, whereby damage of the capacitors caused by contraction of the via-plugs during formation of the capacitors can be suppressed. In addition, the separate fabrication of the plug substrate and the capacitor substrate reduces the restriction on the fabrication process.

As described heretofore, the interposer integrated with capacitors of the present invention, and the fabrication process of the same may have the following configurations. In the method for manufacturing the interposer integrated with capacitors according to the present invention, a configuration may be employed wherein, after bonding together the terminal electrodes of the first substrate and the coupling pads of the second substrate, the first substrate is ground from the rear surface thereof. In this case, a substrate body of the capacitor substrate can be formed having a smaller thickness, while suppressing a damage of the first substrate. The smaller thickness of the substrate body of the capacitor substrate reduces the distance of the interconnection between the LSI and the capacitor, to thereby reduce the inductance L1. In addition, formation of through-holes and filling the through-holes with the via-plugs can be facilitated, and at the same time, the number of choices of the material for the capacitor substrate can be increased.

The capacitor may be formed on the main surface of the substrate body or may be formed above the main surface of the substrate body. The terminal electrodes of the capacitor substrate may be formed to penetrate the cover insulating film.

In the interposer integrated with capacitors of the present invention, a configuration may be employed wherein the terminal electrode of the capacitor substrate and the coupling pad of the plug substrate are coupled together via a bonding electrode, and the gap between the capacitor substrate and the plug substrates is filled with a resin material. The filling with the resin material suppresses degradation of the capacitor.

In the interposer integrated with capacitors of the present invention, a configuration may be employed wherein the substrate body of the capacitor substrate is a semiconductor substrate wherein the main surface and the rear surface thereof are covered by an insulating film, and an insulating film is formed on the circumference of the via-plug of the semiconductor substrate or the sidewall of a through-hole. In this case, the semiconductor substrate may be a silicon substrate.

In the interposer integrated with capacitors of the present invention, a configuration may be employed wherein the substrate body of the capacitor substrate is an insulator substrate. In this case, the insulator substrate may be a glass substrate, a ceramic substrate, or a resin substrate, for example. Since through-holes can be easily formed in a substrate body having a smaller thickness, a variety of materials can be used for the substrate body.

In the interposer integrated with capacitors of the present invention, a configuration may be employed wherein the substrate body of the plug substrate is a semiconductor substrate wherein the main surface and rear surface thereof is covered by an insulating film, and an insulating film may be formed on the circumference of the via-plug of the semiconductor substrate or the sidewall of a through-hole. In this case, the semiconductor substrate may be a silicon substrate, for example.

In the interposer integrated with capacitors of the present invention, a configuration may be employed wherein the substrate body of the plug substrate is an insulator substrate. In this case, the insulator substrate may be a glass substrate, a photosensitive glass substrate, a ceramic substrate, a glass-ceramic substrate, or a resin substrate, for example.

In the interposer integrated with capacitors of the present invention, a configuration may be employed wherein a barrier layer is formed on the rear surface of the terminal electrodes. In this case, upon forming through-holes in the substrate body of the capacitor substrate, the influence exerted onto the rear surface of the terminal electrode can be suppressed.

In the interposer integrated with capacitors of the present invention, a configuration may be employed wherein the substrate body of the capacitor substrate has a thickness of 15 μm or less. In this case, formation of through-holes is facilitated in the substrate body of the capacitor substrate.

In the method for manufacturing an interposer integrated with capacitors according to the third aspect of the present invention, the step of filling through-holes with via-plugs may be further provided. In the method for manufacturing an interposer integrated with capacitors according to the fourth aspect of the present invention, a configuration may be employed wherein each cut substrate obtained by cutting the substrate wherein the capacitors and terminal electrodes are formed is examined, and only a non-defective one is used. Accordingly, even if the product yield of the capacitor substrates is lower, an interposer integrated with capacitors having a higher reliability can be efficiently manufactured.

While the invention has been particularly shown and described with reference to exemplary embodiment thereof, the invention is not limited to these embodiments and modifications. As will be apparent to those of ordinary skill in the art, various changes may be made in the invention without departing from the spirit and scope of the invention as defined in the appended claims.

1-23. (canceled)

24. An interposer integrated with capacitors comprising:
a capacitor substrate including a first substrate body, capacitors formed on a main surface of said first substrate body, a cover insulation film that covers said capacitors, a terminal electrodes connected to an electrode of said capacitor and formed on said cover insulation film; and
a plug substrate including a second substrate body, coupling pads formed on a main surface of said second substrate body corresponding to said terminal electrodes of said capacitor substrate, and via-plugs that penetrate said second substrate body and connected to said coupling pads,
wherein said terminal electrodes of said capacitor substrate and said coupling pads of said plug substrate are bonded together.

25. The interposer integrated with capacitors according to claim 24, wherein said capacitor substrate further includes electrode pads formed on a rear surface of said first substrate body, and via-plugs that connect together said terminal electrodes and said coupling pads.

26. The interposer integrated with capacitors according to claim 24, wherein said capacitor substrate further includes through-holes that expose said terminal electrodes through a rear surface of said first substrate body.

27. The interposer integrated with capacitors according to claim 24, wherein said terminal electrodes of said capacitor substrate penetrate said cover insulation film.

28. The interposer integrated with capacitors according to claim 24, wherein said terminal electrodes of said capacitor substrate and said coupling pads of said plug substrate are coupled together via bonding electrodes, and a gap between said capacitor substrate and said plug substrates is filled with a resin material.

29. The interposer integrated with capacitors according to claim 24, wherein said first substrate body of said capacitor substrate is a semiconductor substrate having a top surface and a rear surface covered by an insulating film.

30. The interposer integrated with capacitors according to claim 29, wherein said semiconductor substrate of said capacitor substrate is a silicon substrate.

31. The interposer integrated with capacitors according to claim 24, wherein said first substrate body of said capacitor substrate is an insulator substrate.

32. The interposer integrated with capacitors according to claim 31, wherein said insulator substrate of said capacitor substrate is a glass substrate.

33. The interposer integrated with capacitors according to claim 31, wherein said insulator substrate of said capacitor substrate is a ceramic substrate.

34. The interposer integrated with capacitors according to claim 31, wherein said insulator substrate of said capacitor substrate is a resin substrate.

35. The interposer integrated with capacitors according to claim 24, wherein said second substrate body of said plug substrate is a semiconductor substrate.

36. The interposer integrated with capacitors according to claim 35, wherein said semiconductor substrate of said plug substrate is a silicon substrate.

37. The interposer integrated with capacitors according to claim 24, wherein said second substrate body of said plug substrate is an insulator substrate.

38. The interposer integrated with capacitors according to claim 37, wherein said insulator substrate of said plug substrate is a glass substrate.

39. The interposer integrated with capacitors according to claim 37, wherein said insulator substrate of said plug substrate is a photosensitive glass substrate.

40. The interposer integrated with capacitors according to claim 37, wherein said insulator substrate of said plug substrate is a ceramic substrate.

41. The interposer integrated with capacitors according to claim 37, wherein said insulator substrate of said plug substrate is a glass-ceramic substrate.

42. The interposer integrated with capacitors according to claim 37, wherein said insulator substrate of said plug substrate is a resin substrate.

43. The interposer integrated with capacitors according to claim 24, wherein a barrier layer is formed on a rear surface of said terminal electrode.

44. The interposer integrated with capacitors according claim 24, wherein said first substrate body of said capacitor substrate has a thickness of 15 μm or less.

45. A method for manufacturing an interposer integrated with capacitors, comprising: forming capacitors on a main surface of a first substrate; covering said capacitors by an insulating film; forming terminal electrodes of said capacitor that penetrate said insulating film; forming a second substrate including coupling pads connected to first via-plugs; bonding together said terminal electrodes of said first substrate and said coupling pads of said second substrate; grinding said first substrate on a rear surface thereof; selectively etching said first substrate from said ground rear surface thereof to form through-holes that expose said terminal electrode of said first substrate.

46. The method for manufacturing an interposer integrated with capacitors according to claim 45, further comprising filling said through-holes with second via-plugs.

47. A method for manufacturing an interposer integrated with capacitors, comprising: forming a plurality of capacitors on a main surface of a first substrate; covering said capacitors by an insulating film; forming terminal electrodes of said capacitors that penetrate said insulating film; cutting said first substrate, on which said capacitors and terminal electrodes are formed, into a plurality of substrate pieces each including at least one of said capacitors; forming second substrate including coupling pads connected to first via-plugs; bonding together said terminal electrodes formed on said substrate pieces and said coupling pads of said second substrate; grinding said substrate pieces on a rear surface thereof; selectively etching said substrate pieces from said ground rear surface thereof to form through-holes that expose said terminal electrodes.
